(19) United States
(12) Patent Application Publication
(10) Pub. No.: US 2021/0357606 A1
(43) Pub. Date: Nov. 18, 2021

(54) FINGERPRINT IDENTIFICATION SENSOR, DISPLAY APPARATUS, AND FINGERPRINT IDENTIFICATION METHOD

(71) Applicant: BOE TECHNOLOGY GROUP CO., LTD., Beijing (CN)

(72) Inventors: Xueyou Cao, Beijing (CN); Rui Xu, Beijing (CN); Lei Wang, Beijing (CN); Haisheng Wang, Beijing (CN); Xiaoliang Ding, Beijing (CN); Changfeng Li, Beijing (CN); Wei Liu, Beijing (CN)

(73) Assignee: BOE TECHNOLOGY GROUP CO., LTD., Beijing (CN)

(21) Appl. No.: 16/344,579

(22) PCT Filed: Nov. 21, 2018
(86) PCT No.: PCT/CN2018/116683

§ 371 Date: Apr. 24, 2019

(30) Foreign Application Priority Data
Dec. 12, 2017 (CN) 201711318932.0

(51) Int. Cl. G06K 9/00; G06K 9/20; H01L 27/146; H01L 27/32

(52) U.S. Cl. CPC G06K 9/0004; G06K 9/2036; G06K 9/2027; H01L 27/3244; H01L 27/14623; H01L 27/14627; H01L 27/3234; H01L 27/14678

(57) ABSTRACT

A fingerprint identification sensor may include a substrate (100), at least a photosensitive element (200) above the substrate (100), and at least a light source assembly (300). The light source assembly (300) may include a point light source (310) and a diffusing structure (320). The diffusing structure (320) may be configured to reduce intensity of light received by the photosensitive element (200) from a center region of the point light source (310).

### CROSS-REFERENCE TO RELATED APPLICATIONS

This application claims benefit of the filing date of Chinese Patent Application No. 201711318932.0 filed on Dec. 12, 2017, the disclosure of which is hereby incorporated in its entirety by reference.

### TECHNICAL FIELD

The present disclosure relates to display technology, and in particular, to a fingerprint identification sensor, a display apparatus, and a fingerprint identification method.

### BACKGROUND

With the rapid development of electronic technology and display technology, the display performance of current display apparatus has also been greatly improved, and the current display apparatus has achieved multiple functions. In addition, with the increase in the functionality of an electronic apparatus with a display apparatus, users also demand higher requirements for safety performance of the electronic apparatus. Therefore, security functions, such as fingerprint identification, are increasingly integrated into display apparatus and electronic apparatus.

### BRIEF SUMMARY

An example of the present disclosure provides a fingerprint identification sensor. The fingerprint identification sensor may include a substrate, at least a photosensitive element above the substrate, and at least a light source assembly. The light source assembly may include a point light source and a diffusing structure. The diffusing structure may be configured to reduce intensity of light received by the photosensitive element from a center region of the point light source.

The diffusing structure may be configured to scatter or shield the light from the center region of the point light source. The diffusing structure may include at least a light shielding layer or a concave lens. The central region of the point light source may include a region where an emission angle of the light emitted by the point light source being within a range between about −30° to about 30°. The diffusing structure may be configured to shield the light emitted from the center region of the point light source or to scatter the light emitted from the center region to have an emission angle in a range of about −50° to about −40° or a range of about 40° to about 50°.

The diffusing structure may include a light shielding structure disposed on a side of the photosensitive element facing the point light source. An orthographic projection of the diffusing structure on the substrate may cover at least an orthographic projection of the center region of the point light source on the substrate.

The diffusing structure may further include a light shielding layer. An orthographic projection of the light shielding layer on the substrate at least partially overlaps the orthographic projection of the central region of the point light source on the substrate, and the orthographic projection of the light shielding layer coincides with an orthographic projection of the photosensitive element on the substrate.

The light shielding layer may be on a side of the light shielding structure facing the point light source. A surface of the light shielding layer facing the point light source may be a convex surface, and the convex surface may be curved toward the point light source.

The light shielding layer and the light shielding structure may constitute a unitary structure and are made of a same material. The diffusing structure may include the concave lens, and an orthographic projection of the point light source on the substrate may be within an orthographic projection of the concave lens on the substrate. An orthographic projection of the photosensitive element on the substrate may not overlap the orthogonal projection of the point light source on the substrate.

The photosensitive element may be at an interval between point light sources. The photosensitive element may be a photodiode.

The fingerprint identification sensor may further include a data transmission circuit which is electrically connected to the photodiode, wherein the data transmission circuit comprises a control switch.

Another example of the present disclosure is a display apparatus. The display apparatus may include the fingerprint identification sensor according to one embodiment of the present disclosure.

Another example of the present disclosure is a fingerprint identification method for a display screen. A fingerprint identification sensor may be disposed on a substrate of the display screen. The fingerprint identification sensor may include at least a photosensitive element and at least a light source assembly. The light source assembly may include a point light source and a diffusing structure. The diffusing structure may be configured to reduce intensity of light received by the photosensitive element from a center region of the point light source. The method may include, during a display period, the point light source is turned off and display is performed on the display screen and, during a fingerprint identification period, the display is turned off, the point light source is turned on and fingerprint identification is performed.

The fingerprint identification sensor may further include a data transmission unit, the data transmission circuit may include a control switch and an amplification circuit, the control switch may be electrically connected to the photosensitive element and the amplification circuit respectively, and the amplification circuit may be connected to a CPU of the display screen. At an initial stage of the fingerprint identification period, the control switch may be turned on, the photosensitive element may be reset. At a final stage of the fingerprint identification period, the control switch may be turned on, the signals generated by the photosensitive element may be read as fingerprint identification sensing signals through the amplification circuit. Durations of the initial stage and the final stage may be respectively within a range of about 10 microseconds to about 500 microseconds.

### BRIEF DESCRIPTION OF THE DRAWINGS

The subject matter which is regarded as the disclosure is particularly pointed out and distinctly claimed in the claims at the conclusion of this specification. The foregoing and other objects, features, and advantages of the disclosure are apparent from the following detailed description taken in conjunction with the accompanying drawings in which:

FIG. 1 is a schematic structural diagram of a fingerprint identification sensor according to an embodiment of the present disclosure;

FIG. 2 is a conceptual verification diagram of a fingerprint identification based on the central region and the peripheral region of the point light source respectively;

FIG. 3 is a schematic diagram of a light emitting angle according to an embodiment of the present disclosure;

FIG. 4a is a schematic structural diagram of a fingerprint identification sensor according to an embodiment of the present disclosure;

FIG. 4b is a schematic structural diagram of a diffusion structure according to one embodiment of the present disclosure;

FIG. 5 is a schematic structural diagram of a fingerprint identification sensor according to an embodiment of the present disclosure;

FIG. 6 is a partial schematic circuit diagram of a fingerprint identification sensor according to an embodiment of the present disclosure;

FIG. 7 is a schematic structural diagram of a display apparatus according to an embodiment of the present disclosure;

FIG. 8 is a timing control diagram of a display apparatus according to an embodiment of the present disclosure.

### DETAILED DESCRIPTION

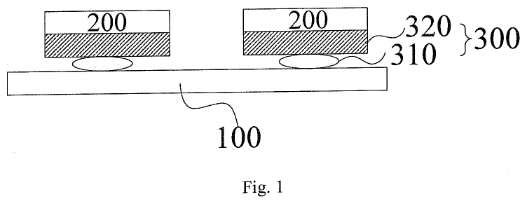

The present disclosure will be explained in further detail with reference to the accompanying drawings and embodiments in order to provide a better understanding by those skilled in the art of the technical solutions of the present disclosure. Throughout the description of the disclosure, reference is made to FIGS. 1-8. When referring to the figures, like structures and elements shown throughout are indicated with like reference numerals.

In the description of the specification, references made to the terms “some embodiments,” “some example embodiments,” and “exemplary embodiments,” “example,” and “specific example,” or “some examples” and the like are intended to refer those specific features and structures, materials or characteristics described in connection with the embodiment or example that are included in at least some embodiments or examples of the present disclosure. The schematic expression of the terms does not necessarily refer to the same embodiment or example. Moreover, the specific features, structures, materials or characteristics described may be included in any suitable manner in any one or more embodiments or examples.

A numerical range modified by “approximately” herein means that the upper and lower limits of the numerical range can vary by 10% thereof. A number modified by “approximately” herein means that the number can vary by 10% thereof.

Unless otherwise defined, technical terms or scientific terms used in this disclosure should have an ordinary meaning understandable to those of ordinary skill in the art to which this disclosure pertains. The “first,” “second,” and similar words used in this disclosure do not denote any order, quantity or importance, but only distinguish between different components. “Including,” “comprising,” and similar terms mean that the elements or objects preceding the word cover the elements or objects listed after the word, but do not exclude additional elements or objects. Coupled or connected, and the like are not limited to physical or mechanical connections, but may also include electrical connections, whether direct or indirect. “Up,” “down,” “left,” “right” and so on are used only to represent the relative positional relationship. When the absolute position of the object to be described changes, the relative positional relationship may also change accordingly. When an element such as a layer, a film, a region or a substrate is referred to as being “on” or “under” another element, the element may be “directly” located on or under another element, or there may be an intermediate element.

At present, for the current electronic apparatus with a fingerprint identification sensor, the structure of the fingerprint identification sensor is very complex and accordingly it is difficult to integrate the fingerprint identification sensor into the display apparatus. This is true mainly because that the current fingerprint identification sensors, especially those based on photosensitive elements, generally have high requirement for the backlight. Therefore, it is desirable to design a backlight element that can meet certain special requirements. For the photosensitive fingerprinting identification apparatus, it is required that the backlight source not only provide a backlight with sufficient brightness, but also that the intensity of the backlight not be too strong, which otherwise would saturate the photosensitive elements. If the backlight is too strong, the photosensitive elements cannot recognize the signal reflected by the finger, thereby resulting in failure of the fingerprint sensor. Because a point light source has strong light intensity at the center region, which may cause saturation of the light sensor, current fingerprint identification sensors generally use a surface light source for fingerprint identification. Therefore, on one hand, it is difficult to integrate the photosensitive fingerprint sensor into the organic light-emitting display apparatus. On the other hand, a surface light source is usually formed by a point light source passing through a light guide plate and/or other structures to homogenize the light, thereby increasing complexity of the structure of the fingerprint identification sensor, which is not conducive to slimming of electronic apparatus.

One embodiment of the present disclosure provides a fingerprint identification sensor. According to the embodiment of the present disclosure. As shown in FIG. 1, the fingerprint identification sensor includes a substrate 100, a plurality of photosensitive elements 200 disposed on the substrate 100, and a plurality of light source assemblies 300. The light source assembly 300 includes a point light source 310 and a diffusing structure 320. The diffusing structure 320 can make intensity of the light received by the photosensitive element 200 smaller than the intensity of the light emitted from the central region of the point light source 310. That is, the point light source 310 is configured so that the light emitted from the center region does not directly irradiate the finger and then be reflected to the photosensitive element 200. Instead, the point light source 310 is configured so that the light emitted from the center region first irradiates the diffusing structure 320 before irradiating the finger. The light emitted from the rest of the region can be emitted out of the substrate 100 and reflected back to the photosensitive element 200. The fingerprint identification sensor according to embodiments of the present disclosure can utilize a point light source as the backlight of the fingerprint identification sensor by adding a simple diffusing element, thereby simplifying the structure of the fingerprint identification sensor. As such, it is easy to integrate the fingerprint identification sensor into the organic light-emitting display apparatus.

In the following, according to specific embodiments of the present disclosure, a detailed description will be provided of the elements of the fingerprint identification sensor and the principles that the point light source can be used to realize fingerprint identification.

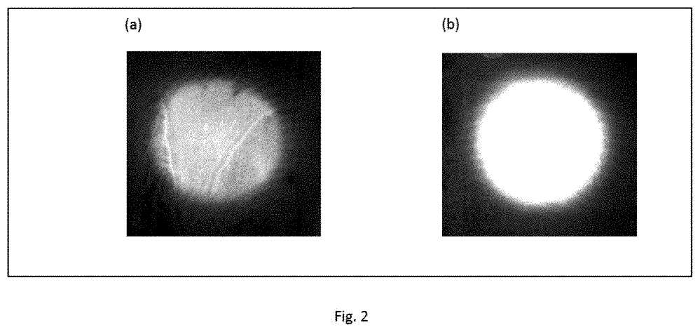

As mentioned before, unlike the light sources that have been homogenized, the light emitted by a point light source has different emitting angles and intensities. Specifically, the light emitted from the central region of the point light source, i.e., the region where the emission angle is small, has relatively high intensity. The light from the peripheral region, i.e., the region where the emission angle is large, has relatively low intensity. As shown in FIG. 2, if the fingerprint identification sensor uses the point light source, the light intensity in the center region, as shown in FIG. 2(b), is strong and the photosensitive element is saturated. Accordingly, the fingerprint information cannot be obtained. In contrast, from light emitted from the peripheral region of the point light source, as shown in FIG. 2(a), the fingerprint information can be clearly seen. Therefore, direct application of a point light source as the light source of the fingerprint identification sensor negatively affects performance of the fingerprint identification sensor.

In one embodiment, the light emitted by the point light source at an emission angle within a range of about −30° to about 30° has relatively high intensity, which can saturate the photosensitive elements and negatively affect acquisition of fingerprint information. The light emitted at an emission angle within the ranges of about −40° to about −50° and about 40° to about 50° is more moderate, and is suitable for fingerprint identification. When the light emission angle is further increased, the light intensity is weakened more severely, and the brightness of the backlight is insufficient, which also negatively affects accuracy of the fingerprint identification. Therefore, according to one embodiment of the present disclosure, by disposing a plurality of diffusing structures cooperating with a plurality of point light sources 310, light in the central region (light emitting angle within a range of about −30° to about 30°) is shielded or scattered so that the light is not directly reflected to the photosensitive elements for sensing the fingerprint information, thereby avoiding saturating the photosensitive elements due to the backlight being too bright.

According to one embodiment of the present disclosure, the “central region” of the point light source 310 includes a region where the light emitted by the point light source has an emission angle within the range of about −30° to about 30°, and the diffusing structure 320 is configured to shield the photosensitive element from the light emitted from the center region, or to scatter the light emitted from the center region to have an emission angle within the range of about −50° to about −40° and about 40° to about 50° out from the substrate, thereby improving performance of sensing the fingerprint information by the photosensitive element.

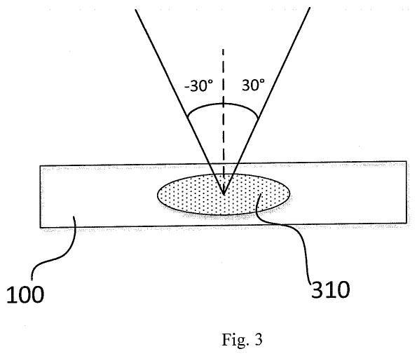

It should be noted that, in the present disclosure, the light emitting angle perpendicular to a plane where the point light source is located is defined to be 0 degrees. As shown in FIG. 3, the term “light emitting angle” refers to the angle between the light emitting direction and the direction perpendicular to the plane where the point light source is located (that is, the direction of the light has an emitting angle of 0 degrees). The positive and negative characteristics of the light emission angles are only used to indicate the relative direction of light emitting angles. That is, as shown in FIG. 3, if the light emitting direction is at a counterclockwise direction from the direction of the light having an emitting angle of 0 degrees, the emission angle is a negative angle. If the light emitting direction is at a clockwise from the direction of the light having an emitting angle of 0 degrees, the emission angle is a positive angle.

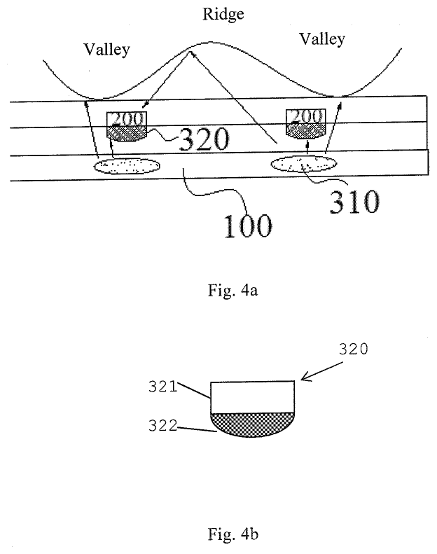

According to one embodiment of the present disclosure, the diffusing structure 320 may be composed of a concave lens and/or an opaque layer having a light shielding function. In one embodiment, as shown in FIGS. 4a and 4b, the diffusing structure 320 may include a light shielding structure 321 and a light shielding layer 322, so that the light in the central region can be easily blocked. The specific position and thickness of the light-shielding layer and the distance between the light-shielding layer and the point light source 310 are not particularly limited, and those skilled in the art can design according to actual needs as long as the light-shielding layer can block the light emitted from the central region. For example, an orthographic projection of the light-shielding layer on the substrate 100 may at least partially overlap an orthographic projection of the center region of the point light source on the substrate. In one embodiment, an orthographic projection of the light-shielding layer on the substrate 100 may completely overlap the orthographic projection of the central region of the point light source on the substrate. In one embodiment, the side of the light-shielding layer facing the point light source may have a convex structure as shown in the FIG. 4a. Since the point light source 310 is a planar divergent light source, the light shielding layer has an arc-shaped protrusion so that the light in the central region can be blocked at a relatively shorter distance to the point light source 310. As a result, only light from the point light sources 310 with appropriate light emission angles can be emitted out from the substrate 100, and irradiate a finger above the fingerprint identification sensor. Subsequently, the light is reflected by different parts of the finger such as ridges and valleys thereof as shown in the FIG. 4a and received by the photosensitive element 200 to generate a photosensitive electrical signal. The light intensity of the light reflected from different parts of the finger is different, thereby affecting the generated light-sensitive electrical signals. Finally, based on the photosensitive electrical signals of a plurality of photosensitive elements 200, identification of the fingerprint information is achieved. In this embodiment, the photosensitive element 200 may be disposed on a side of the light-shielding layer opposite from the point light source 310. Thus, on the one hand, the light shielding layer can be used to block the light emitted from the central region of the point light source. On the other hand, the light shielding layer provided below can be used to prevent the light emitted from the point light source 310 from entering the photosensitive element 200 without being reflected by the finger.

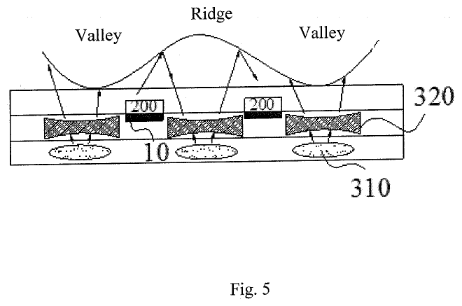

According to one embodiment of the present disclosure, the diffusing structure 320 may also be a concave lens. According to one embodiment of the present disclosure, as shown in FIG. 5, the light emitted from the center region of the point light source may be scattered by the diffusing structure 320 to change the light exiting angle so as to prevent the intensity of the light from being too strong and affecting the fingerprint sensing. In one embodiment, by adjusting the position and structure of the concave lens, and the distance of the concave lens to the point light source 310, the light emitted from the central region first enters the concave lens and then exits so that the light is scattered to have an emission angle within a range of about −50° to about −40° and about 40° to about 50°, and then emits out from the substrate. In one embodiment, the orthographic projection of the point light source 310 on the substrate may be within the orthographic projection of the concave lens on the substrate. As such, the light emitted from the central region of the point light source can be easily scattered. In addition, in order to prevent the light emitted from the point light source from being directly emitted to the light receiving element 200 from the side facing the point light source 310 without being reflected by the ridges and valleys of the finger, a light shielding layer 10 may be disposed on the side of the photosensitive element 200 facing the point light source 310. It should be noted that the light shielding layer 10 herein does not need to have the function of blocking light emitted from a specific region of the point light source. Therefore, the light shielding layer 10 needs only to cover the surface of the lower portion of the photosensitive element 200, but does not need to have a specific shape and thickness. Moreover, according to one embodiment of the present disclosure, the orthographic projection of the photosensitive element 200 on the substrate does not overlap the orthogonal projection of the point light source on the substrate. In one embodiment, since the light diffusing structures 320 also transmit the light, the photosensitive elements 200 are disposed at intervals among the plurality of light diffusing structures 320. Such an arrangement is advantageous for the light-receiving element 200 to receive more reflected light, thereby facilitating improvement of sensitivity of the fingerprint identification.

According to one embodiment of the present disclosure, the specific type of the above-described photosensitive element 200 is not particularly limited as long as a photosensitive signal can be generated. For example, according to a specific embodiment of the present disclosure, the photosensitive element 200 may include a photodiode, a PIN junction capable of generating a photonic circuit, or a red organic photodiode formed of an OPD material.

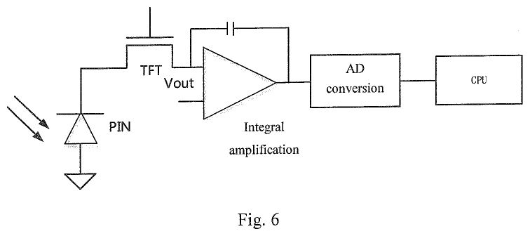

According to one embodiment of the present disclosure, the fingerprint identification sensor may further include a data transmission circuit. The data transmission circuit is electrically connected to the photosensitive element, and the data transmission circuit includes a control switch and an amplification circuit. As such, the sensitivity of the fingerprint sensor can be further improved. Specifically, as shown in FIG. 6, the control switch may be a thin film transistor (such as the TFT shown in FIG. 6). The connection and disconnection between the data transmission circuit and the photodiode (such as the PIN shown in FIG. 6) are controlled by the switch. When it is necessary to sense the photo-generated current generated in the PIN junction, the TFT is turned on. The electrical signal can be output through an integral amplification or other amplification circuit and transmitted to an analog-to-digital conversion module as shown in the FIG. 6 and finally to the CPU to perform data processing.

In another embodiment of the present disclosure, the present disclosure provides a display apparatus. According to this embodiment of the present disclosure, the display apparatus includes the fingerprint identification sensor described above. Therefore, the display apparatus has all the features and advantages of the fingerprint identification sensor described above, which will not be described herein. In general, the display apparatus has at least one of the following advantages: the fingerprint identification function can be implemented with a relatively simple structure, and the fingerprint identification accuracy is high.

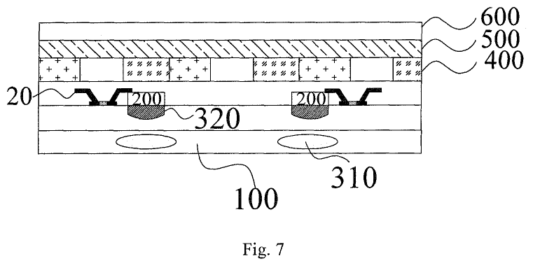

According to one embodiment of the present disclosure, the display apparatus may be an organic light emitting display apparatus. As shown in FIG. 7, the organic light emitting display apparatus may further include structures such as an organic light emitting layer 400, a polarizer 500, and a cover glass 600. As a result, the structure of the display apparatus can be further simplified. According to one embodiment of the present disclosure, the driving transistor 20 of the organic light emitting display apparatus may be disposed in the same layer as the control switch (that is, a thin film transistor, not shown in FIG. 7) of the fingerprint identification sensor described above. As a result, the structure of the display apparatus can be further simplified.

In yet another embodiment of the present disclosure, the present disclosure provides a fingerprint identification method for a display screen. According to one embodiment of the present disclosure, a fingerprint identification sensor is disposed on the display screen, and the fingerprint identification sensor may be the previously described fingerprint identification sensor according to embodiments of the present disclosure. According to the embodiments of the present disclosure, the method includes turning off the point light source and performing the display during the display period, and turning on the point light source and performing fingerprint identification during the fingerprint identification period. As such, identification of the fingerprint can be easily performed, and the display and light signals of the point light source are prevented from interfering with each other.

According to one embodiment of the present disclosure, detailed description will be given in the following to each step of the method:

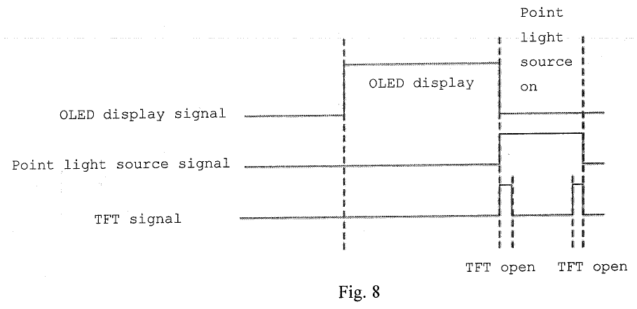

As described above, the fingerprint identification sensor may further include a data transmission circuit including a control switch and an amplification circuit. The amplification circuit is connected to the CPU of the display screen. As shown in FIG. 8, the method includes the following:

During the OLED display period, the point light source is turned off and display on the display screen is performed. During the fingerprint identification period, the point light source is turned on. The display frequencies of the OLED and the point light source are higher than 60 Hz, and higher than the identification frequency of human eye. As such, the human eye is not affected in reading the OLED display content. The above-mentioned timing control is mainly to prevent the display and the light signals of the point light sources from interfering with each other. At an initial stage of the fingerprint identification period, the control switch (e.g., TFT) is first turned on. That is, the control switch is first controlled to reset the photo-generated current generated by the photosensitive element. The charge generated in the display period is removed by the resetting, thereby reducing influence of noise and improving the sensing accuracy. That is to say, the signal generated by the photosensitive element is exported at this time, but the signal is not read as a fingerprint identification sensor signal through the amplification circuit. At a final stage of the fingerprint identification period, after the point light source is turned on for a period of time, the control switch is turned on again, and the photo-generated current accumulated in the photosensitive element is transmitted to the integral amplification circuit. The photocurrent at this time is a signal that eliminates the noise charge accumulated in the display period, and includes fingerprint information, so that front end fingerprint information can be collected. That is, at this time, the control switch is turned on, the signal generated by the photosensitive element is exported, and the signal is read as a fingerprint identification sensor signal through the amplification circuit, and then the control switch is turned off to complete the sensing of the fingerprint information.

According to one embodiment of the present disclosure, the durations of the initial stage and the final stage of fingerprint identification period described above are independently 10-500 microseconds. For example, it can be 200 microseconds or 100 microseconds. As a result, the interference of the non-fingerprint identification photocurrent signal generated by the lighting of the screen during the display period can be easily eliminated. It should be noted that the time when the point light source is turned on during the usual fingerprint identification is in a range of ten milliseconds to one hundred milliseconds. Therefore, the opening and closing of the above-mentioned control switch (the initial stage and the final stage of the fingerprint identification period) neither affect the sensitivity of the fingerprint identification reaction nor cause a significant extension of the fingerprint identification time.

The principles and the embodiments of the disclosure are set forth in the specification. The description of the embodiments of the present disclosure is only used to help one to understand the method of the present disclosure and the core idea thereof. Meanwhile, for a person of ordinary skill in the art, the disclosure relates to the scope of the disclosure, and the technical scheme is not limited to the specific combinations of the technical features, but should also cover other technical schemes which are formed by combining the technical features or the equivalent features of the technical features without departing from the inventive concept. For example, technical schemes may be obtained by replacing the features described above as disclosed in this disclosure (but not limited to) with similar features.

### DESCRIPTION OF THE REFERENCE SIGNS

100: substrate; 200: photosensitive element; 300: light source assembly; 310: point light source; 320: diffusing structure; 10: black matrix; 20: drive transistor; 400: organic light emitting layer, 500: polarizer; 600: cover glass.

1. A fingerprint identification sensor, comprising:
a substrate;
at least a photosensitive element above the substrate; and
at least a light source assembly, the light source assembly comprising a point light source and a diffusing structure,
wherein the diffusing structure is configured to reduce intensity of light received by the photosensitive element from a center region of the point light source.

2. The fingerprint identification sensor according to claim 1, wherein the diffusing structure is configured to scatter or shield the light from the center region of the point light source.

3. The fingerprint identification sensor according to claim 1, wherein the diffusing structure comprises at least a light shielding layer or a concave lens.

4. The fingerprint identification sensor according to claim 2, wherein the central region of the point light source comprises a region where an emission angle of the light emitted by the point light source being within a range between about −30° to about 30°, and
wherein the diffusing structure is configured to shield the light emitted from the center region of the point light source or to scatter the light emitted from the center region to have an emission angle in a range of about −50° to about 40° or a range of about 40° to about 50°.

5. The fingerprint identification sensor according to claim 4, wherein the diffusing structure comprises a light shielding structure disposed on a side of the photosensitive element facing the point light source.

6. The fingerprint identification sensor according to claim 4, wherein an orthographic projection of the diffusing structure on the substrate covers at least an orthographic projection of the center region of the point light source on the substrate.

7. The fingerprint identification sensor according to claim 6, wherein the diffusing structure further comprises a light shielding layer, an orthographic projection of the light shielding layer on the substrate at least partially overlaps the orthographic projection of the central region of the point light source on the substrate, and the orthographic projection of the light shielding layer coincides with an orthographic projection of the photosensitive element on the substrate.

8. The fingerprint identification sensor according to claim 7, wherein the light shielding layer is on a side of the light shielding structure facing the point light source.

9. The fingerprint identification sensor according to claim 8, wherein a surface of the light shielding layer facing the point light source is a convex surface, and the convex surface is curved toward the point light source.

10. The fingerprint identification sensor according to claim 9, wherein the light shielding layer and the light shielding structure constitute a unitary structure and are made of a same material.

11. The fingerprint identification sensor according to claim 3, wherein the diffusing structure comprises the concave lens, and an orthographic projection of the point light source on the substrate is within an orthographic projection of the concave lens on the substrate.

12. The fingerprint identification sensor according to claim 11, wherein an orthographic projection of the photosensitive element on the substrate does not overlap the orthogonal projection of the point light source on the substrate.

13. The fingerprint identification sensor according to claim 12, wherein the photosensitive element is at an interval between point light sources.

14. The fingerprint identification sensor according to claim 1, wherein the photosensitive element is a photodiode.

15. The fingerprint identification sensor according to claim 14, further comprising a data transmission circuit which is electrically connected to the photodiode, wherein the data transmission circuit comprises a control switch.

16. A display apparatus, comprising the fingerprint identification sensor according to claim 1.

17. A fingerprint identification method for a display screen, wherein a fingerprint identification sensor is disposed on a substrate of the display screen, the fingerprint identification sensor comprising at least a photosensitive element and at least a light source assembly, and the light source assembly comprising a point light source and a diffusing structure, the diffusing structure being configured to reduce intensity of light received by the photosensitive element from a center region of the point light source, the method comprising:
during a display period, the point light source is turned off and display is performed on the display screen; and
during a fingerprint identification period, the display is turned off, the point light source is turned on and fingerprint identification is performed.

18. The fingerprint identification method according to claim 17, wherein the fingerprint identification sensor further comprises a data transmission unit, and the data transmission circuit comprises a control switch and an amplification circuit, and the control switch is electrically connected to the photosensitive element and the amplification circuit respectively, and the amplification circuit is connected to a CPU of the display screen;
at an initial stage of the fingerprint identification period, the control switch is turned on, the photosensitive element are reset; and
at a final stage of the fingerprint identification period, the control switch is turned on, the signals generated by the photosensitive element are read as fingerprint identification sensing signals through the amplification circuit.

19. The fingerprint identification method according to claim 18, where durations of the initial stage and the final stage are respectively within a range of about 10 microseconds to about 500 microseconds.
